(19) United States
(12) Patent Application Publication
(10) Pub. No.: US 2026/0013079 A1
(43) Pub. Date: Jan. 8, 2026

(54) HEAT DISSIPATION SYSTEM

(71) Applicant: Acer Incorporated, New Taipei City (TW)

(72) Inventors: Yu-Ming Lin, New Taipei City (TW); Wen-Neng Liao, New Taipei City (TW); Cheng-Wen Hsieh, New Taipei City (TW); Tsung-Ting Chen, New Taipei City (TW); Jau-Han Ke, New Taipei City (TW); Chun-Chieh Wang, New Taipei City (TW); Chi-Tai Ho, New Taipei City (TW); Kuan-Lin Chen, New Taipei City (TW)

(73) Assignee: Acer Incorporated, New Taipei City (TW)

(21) Appl. No.: 19/329,504

(22) Filed: Sep. 15, 2025

Related U.S. Application Data
(63) Continuation of application No. 18/306,982, filed on Apr. 25, 2023, now Pat. No. 12,439,559.

(30) Foreign Application Priority Data
Apr. 28, 2022 (TW) 111116260

(51) Int. Cl. H05K 7/20; G06F 1/20

(52) U.S. Cl. CPC H05K 7/20336; G06F 1/203; G06F 1/206; H05K 7/20172; H05K 7/20381

(57) ABSTRACT

A heat dissipation system suitable for a portable electronic device with two heat sources is provided. The portable electronic device has a first and a second heat sources and a casing for receiving the first and the second heat sources. The heat dissipation system disposed in the casing comprises a first centrifugal fan having a first main outlet and the first sub outlet, a first gate disposed at the first sub outlet, and a control unit electrically connected to the first gate, wherein the control unit drives the first gate to open or close the first sub outlet according to a load of the first and the second heat sources. The first heat source provides heat transferring to the first main outlet, and the second heat source provides heat transferring to the first main outlet and the first sub outlet.

### CROSS-REFERENCE TO RELATED APPLICATION

This application is a continuation application of and claims the priority benefit of a prior application Ser. No. 18/306,982, filed on Apr. 25, 2023, now allowed. The prior application Ser. No. 18/306,982 claims the priority benefit of Taiwan application serial no. 111116260, filed on Apr. 28, 2022. The entirety of the above-mentioned patent application is hereby incorporated by reference herein and made a part of this specification.

### BACKGROUND

### Technical Field

The disclosure relates to a heat dissipation system.

### Description of Related Art

With the change of people's computer habits, laptops have become a very important product type in the market. Laptops are small and portable, so people often take them with them to work, to do some paperwork in the office, to read articles or videos online at a coffee shop, or to play a few video games with their friends. If the user specifically requires the smoothness or detail of the video game on the laptop, then the laptop needs to be equipped with a higher-end processor and display chip. However, higher-end processors and display chips are associated with the problem of excessive heat generation, and the size of laptops is limited, so the design of heat dissipation is often less than ideal.

Traditionally, some laptops are designed with fans to carry the heat out of the laptop using air flow. However, as the performance of laptops becomes more and more advanced, the heat generated by laptops also increases dramatically, and as laptops are used in different states, there is a need for different heat dissipation conditions to meet various heat dissipation needs in an efficient way.

### SUMMARY

The disclosure provides a heat dissipation system in which a gate is driven to open and close a sub outlet of a dual outlet fan according to a load state of heat sources, and an efficient heat dissipation means is provided to meet different heat dissipation needs.

The heat dissipation system of the disclosure is suitable for a portable electronic device with multiple heat sources. The heat dissipation system includes a fan, two heat dissipation fin sets, a gate, a first heat pipe, a second heat pipe, and a control unit. The fan is a centrifugal fan and has a main outlet and a sub outlet, the heat dissipation fin sets are disposed respectively at the main outlet and the sub outlet, and the gate is disposed at the sub outlet. The first heat pipe thermally contacts the heat sources and the heat dissipation fin set located at the main outlet. The second heat pipe thermally contacts one of the heat sources and the two heat dissipation fin sets. The control unit is electrically connected to the gate to drive the gate to open or close the sub outlet according to a load of the heat sources.

Based on the above, the portable electronic device has multiple heat sources, the fan of the heat dissipation system has the main outlet and the sub outlet, and the heat sources thermally contact the heat dissipation fin at the main outlet and the sub outlet by different heat pipes, and the sub outlet is controlled by the gate to open or close to form a two-way heat dissipation path or a one-way heat dissipation path. In this way, the control unit may correspondingly open and close the sub outlet according to the respective load state of the heat sources, and use the two-way heat dissipation path or the one-way heat dissipation path as a heat dissipation means to meet different heat dissipation needs.

In other words, since the internal space of the portable electronic device is a multi-heat source setting environment, different load states will exist with different usage conditions, which cannot be handled by the single heat dissipation means of existing technology. Therefore, it is necessary to use the heat dissipation system of the disclosure to provide the corresponding heat dissipation means according to the load state of the heat sources by setting the fan, the heat pipe, and the gate, so that the heat dissipation system may improve the heat dissipation efficiency and optimize the operation efficiency.

To make the aforementioned more comprehensible, several accompanied with drawings are described in detail as follows.

### BRIEF DESCRIPTION OF THE DRAWING

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is an internal schematic diagram of a portable electronic device according to an embodiment of the disclosure.

FIG. 2 is a schematic diagram of electrical connection of relevant components of a heat dissipation system of the disclosure.

FIG. 3A is a schematic diagram of a first fan of FIG. 1.

FIG. 3B is a schematic diagram of a gate of FIG. 1.

FIG. 4 and FIG. 5 are schematic diagrams of the heat dissipation system of FIG. 1 in different states, respectively.

FIG. 6 is a schematic diagram of a heat dissipation system according to another embodiment of the disclosure.

### DESCRIPTION OF THE EMBODIMENTS

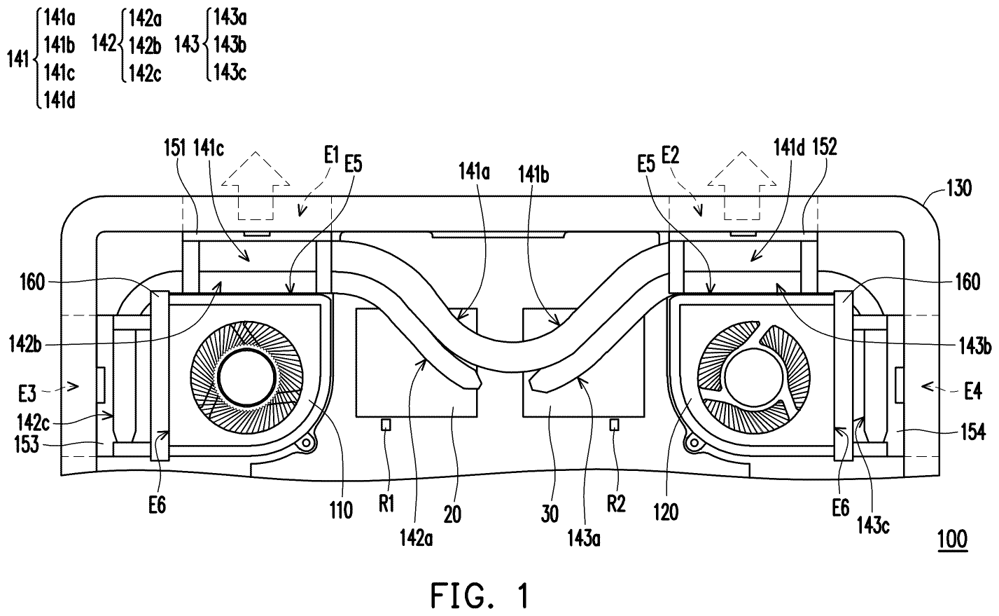

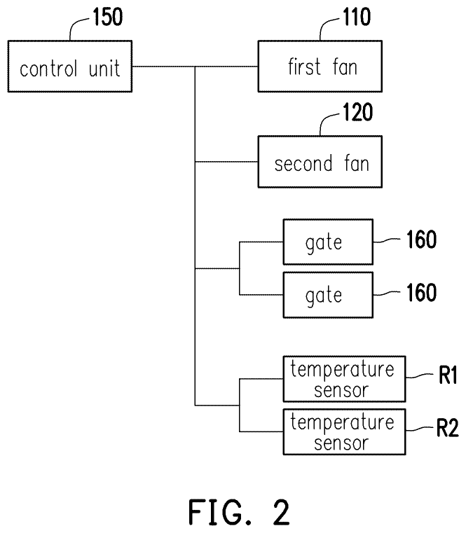

FIG. 1 is an internal schematic diagram of a portable electronic device according to an embodiment of the disclosure, and only a part related to the technical features of this embodiment is shown here. FIG. 2 is a schematic diagram of electrical connection of relevant components of a heat dissipation system of the disclosure. Referring to FIG. 1 and FIG. 2 at the same time, according to this embodiment, a heat dissipation system 100 is suitable for a portable electronic device (e.g. a laptop computer or a tablet computer) with two heat sources 20 and 30. The heat sources 20 and 30 are disposed in the internal space of a casing 130. The heat source 20 is, for example, a display chip (GPU), and the heat source 30 is, for example, a central processing unit (CPU). The heat dissipation system 100 includes a first fan 110, a second fan 120, heat dissipation fin sets 151 to 154, a gate 160, a first heat pipe 141, a second heat pipe 142, a third heat pipe 143, and a control unit 150. It should be noted here that the serial numbers added to the names of the components of the disclosure, such as first, second, are for identification purposes only, and the structural features of the components themselves are actually the same.

The first fan 110 and the second fan 120 are centrifugal fans respectively, and each has a main outlet E5 and a sub outlet E6. The heat dissipation fin sets 151 to 154 are respectively disposed at the main outlets E5 and the sub outlets E6. The gate 160 is respectively disposed at the sub outlets E6. The casing 130 further has multiple exhaust vents E1 to E4 corresponding to the heat dissipation fin sets 151 to 154, the main outlets E5, and the sub outlets E6, respectively, as shown in FIG. 1.

Taking the casing 130 of the portable electronic device 100 as a reference, the heat dissipation system 100 is disposed in the casing 130, the main outlets E5 are located on a rear side of the casing 130, and the sub outlets E6 are located on a side of the casing 130. Taking a laptop computer as an example, a user operates the portable electronic device from a front side of the casing 130, the rear side is a pivot point between the casing 130 and a screen (not shown), and the front side and the rear side are two sides of the casing 130 opposite each other.

Furthermore, the first heat pipe 141 according to this embodiment thermally contacts the heat sources 20 and 30, and the heat dissipation fin sets 151 and 152 located at the main outlets E5. The second heat pipe 142 thermally contacts one of the heat sources (i.e., the heat source 20), and thermally contacts the heat dissipation fin sets 151 and 153 at the main outlet E5 and the sub outlet E6 of the same fan (i.e., the first fan 110). The third heat pipe 143 thermally contacts the other one of the heat sources (i.e., the heat source 30), and thermally contacts the heat dissipation fin sets 152 and 154 at the main outlet E5 and the sub outlet E6 of the same fan (i.e., the second fan 120). The thermal contact here refers to the smooth transfer of heat between components, not limited to structural contact.

Further, the first heat pipe 141 has a heat absorption section 141a thermally contacting the heat source 20, a heat absorption section 141b thermally contacting the heat source 30, a heat dissipation section 141c thermally contacting the heat dissipation fin set 151, and a heat dissipation section 141d thermally contacting the heat dissipation fin set 152. Therefore, heat generated by the heat source 20 is absorbed from the heat absorption section 141a, and then transmitted to the heat dissipation section 141c, and the heat is smoothly discharged from the casing 130 through the exhaust vent E1 by air flow generated from the main outlet E5 by the heat dissipation fin set 151 and the first fan 110. Relatively, heat generated by the heat source 30 is absorbed from the heat absorption section 141b, and then transmitted to the heat dissipation section 141d, and the heat is smoothly discharged from the casing 130 through the exhaust vent E2 by air flow generated from the main outlet E5 by the heat dissipation fin set 152 and the second fan 120.

The second heat pipe 142 has a heat absorption section 142a thermally contacting the heat source 20, a heat dissipation section 142b thermally contacting the heat dissipation fin set 151, and a heat dissipation section 142c thermally contacting the heat dissipation fin set 153. Therefore, heat generated by the heat source 20 is absorbed from the heat absorption section 142a, and then transmitted to the heat dissipation section 142b and the heat dissipation section 141c, and the heat is smoothly discharged from the casing 130 through the exhaust vent E1 by air flow generated from the main outlet E5 by the heat dissipation fin set 151 and the first fan 110, and another portion of the heat is smoothly discharged from the casing 130 through the exhaust vent E3 by air flow generated from the sub outlet E6 by the heat dissipation fin set 153 and the first fan 110.

The third heat pipe 143 has a heat absorption section 143a thermally contacting the heat source 30, a heat dissipation section 143b thermally contacting the heat dissipation fin set 152, and a heat dissipation section 143c thermally contacting the heat dissipation fin set 154. Therefore, heat generated by the heat source 30 is absorbed from the heat absorption section 143a, and then transmitted to the heat dissipation section 143b and the heat dissipation section 143c, and the heat is smoothly discharged from the casing 130 through the exhaust vent E2 by air flow generated from the main outlet E5 by the heat dissipation fin set 152 and the second fan 120, and another portion of the heat is smoothly discharged from the casing 130 through the exhaust vent E4 by air flow generated from the sub outlet E6 by the heat dissipation fin set 154 and the second fan 120.

Based on the corresponding configuration of the first heat pipe 141, the second heat pipe 142, and the third heat pipe 143, the heat generated by the heat sources 20 and 30 may be smoothly dissipated out of the casing 130, respectively. Here, the heat transfer technology of the heat pipe is known, and therefore will not be repeated in the following.

Furthermore, referring to FIG. 2, the heat dissipation system 100 further includes temperature sensors R1 and R2 correspondingly disposed beside the heat sources 20 and 30 and do not affect each other, so as to sense temperature of the heat sources 20 and 30 respectively. The control unit 150 is electrically connected to the first fan 110, the second fan 120, the gate 160, and the temperature sensors R1 and R2. The control unit 150 drives the gate 160 to open or close the sub outlets E6 of the first fan 110 and the second fan 120 according to temperature sensing values of the two temperature sensors R1 and R2. Here, the control unit 150 may be another control chip or control circuit in the portable electronic device different from the central processing unit (i.e., the heat source 30), or may be the central processing unit itself.

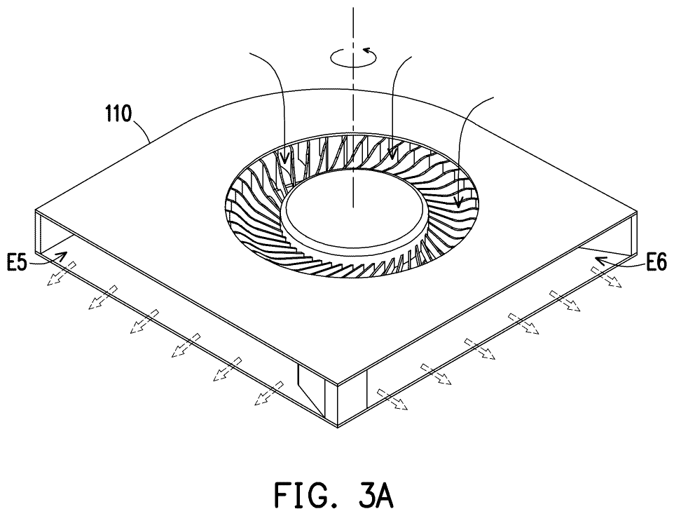

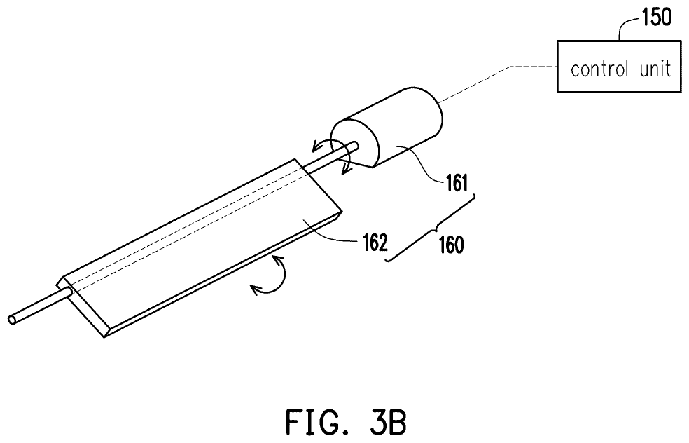

FIG. 3A is a schematic diagram of a first fan of FIG. 1. FIG. 3B is a schematic diagram of a gate of FIG. 1. Referring to FIG. 3A and FIG. 3B and comparing with FIG. 1, it should be mentioned first that the first fan 110 and the second fan 120 are centrifugal fans with dual outlets and are identical in structure to each other, with only the top and bottom inverted in the configuration shown in FIG. 1. Furthermore, for the individual first fan 110 or the second fan 120, quantity of flow of air flow when the main outlet E5 and the sub outlet E6 are both open is 120% of quantity of flow of air flow when the main outlet E5 is open and the sub outlet E6 is closed, while maintaining the same system noise. However, the static pressure generated by the fan (the first fan 110 or the second fan 120) will decrease due to the increase in the number of outlets (both the main outlet E5 and the sub outlet E6 are open). Accordingly, with the outlet diameter or the outline of the flow channel, a ratio of the quantity of flow of air flow of the main outlet E5 to the quantity of flow of air flow of the sub outlet E6 according to this embodiment may be adjusted=6:4. In addition, the gate 160 disposed at the sub outlet E6 includes a motor 161 and a baffle 162. The control unit 150 is electrically connected to the motor 161, and the baffle 162 is connected to the motor 161 and is driven by the motor 161 to rotate up or down to open or close the sub outlet E6 (also equivalent to increasing or decreasing the number of the outlets). A designer may adjust the ratio of quantity of flow appropriately according to the needs.

Based on the configuration of the components, the control unit 150 of the disclosure may drive the gate 160 to open or close the sub outlet E6 according to the load state of the heat sources 20 and 30, and achieve the required heat dissipation effect by efficient means, as described in detail below.

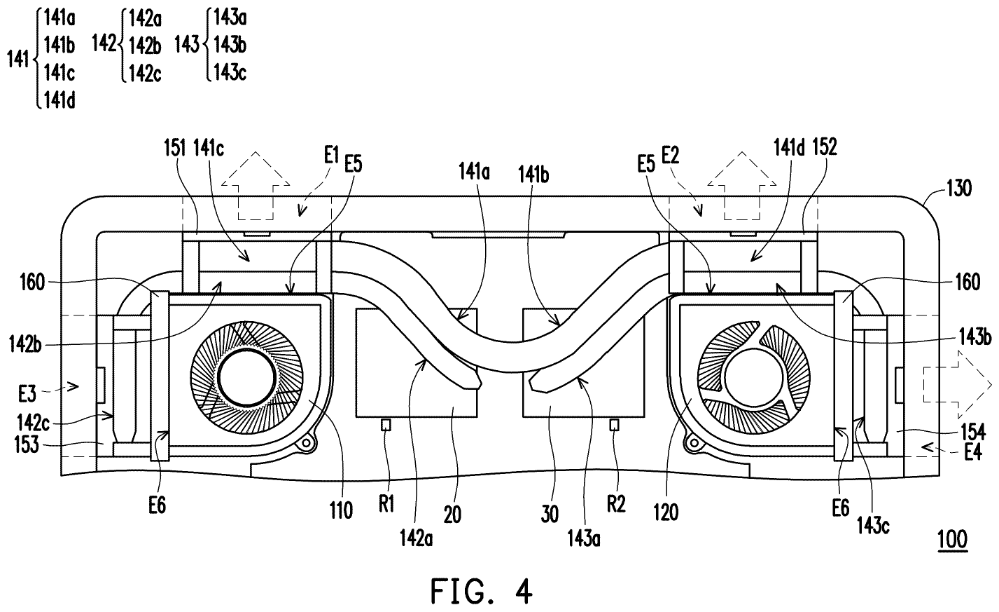

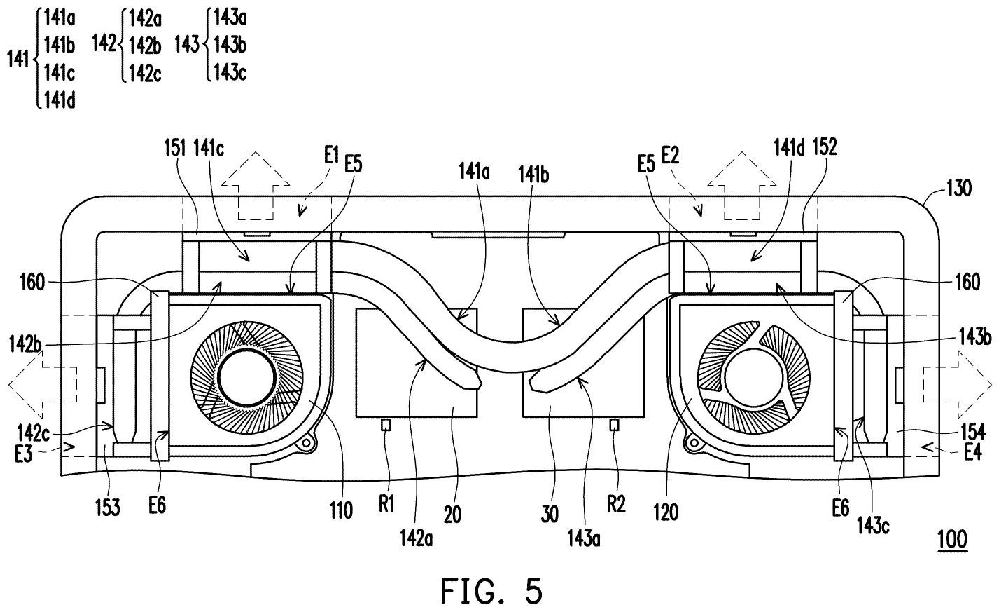

FIG. 4 and FIG. 5 are schematic diagrams of the heat dissipation system of FIG. 1 in different states, respectively. Referring to FIG. 1, FIG. 4, and FIG. 5 at the same time, since the first fan 110 and the second fan 120 according to this embodiment have the features related to air flow, it is necessary to adjust the opening and closing state of the sub outlet E6 of the first fan 110 and the second fan 120 in response to the different load states of the heat sources 20 and 30 in order to optimize the operation efficiency of the heat dissipation system 100.

First, as shown in FIG. 1, the heat sources 20 and 30 are at low load, so the control unit 150 drives the gate 160 to close the respective sub outlets E6 of the first fan 110 and the second fan 120, that is, in this state, it is sufficient for the first fan 110 and the second fan 120 to dissipate the heat from the heat source 20 and 30 with the air flow generated by their respective main air outlets E5. In other words, the first fan 110 and the second fan 120 may each smoothly dissipate the heat generated by the heat sources 20 and 30 at low loads with a single outlet. At the same time, this may also avoid the noise generated by multiple outlets and increase the comfort level of the user when operating the portable electronic device.

Next, as shown in FIG. 4, the heat source 30 is at high load while the heat source 20 is at low load. Therefore, the control unit 150 drives the gate 160 at the second fan 120 to open the sub outlet E6 corresponding to the exhaust vent E4, so that the air flow of the second fan 120 may be increased to facilitate the heat dissipation for the heat source 30 at high load. At the same time, the first fan 110 and the gate 160 located there maintain in the same state as shown in FIG. 1, thus avoiding unnecessary energy waste.

Conversely, when the heat source 30 is at a low load and the heat source 20 is at a high load, the gate 160 at the first fan 110 is opened instead, while the gate 160 at the second fan 120 is left closed.

Next, as shown in FIG. 5, the heat sources 20 and 30 are in a high load state, then the control unit 150 drives the two gates 160 to open the sub outlets E6 of the first fan 110 and the second fan 120, so that the first fan 110 and the second fan 120 are in a dual outlet heat dissipation state to facilitate full heat dissipation of the heat sources 20 and 30.

To put it simply, for a single fan (the first fan 110 or the second fan 120), if the air flow generated by opening only the main outlet E5 is defined as 1 unit, and the air flow may be increased by 20% by additionally opening the sub outlet E6, then the combined air flow of the main outlet E5 and the sub outlet E6 is 1.2 units. In response to the location of the main outlet E5 and the sub outlet E6 in relation to the centrifugal fan, a ratio of the quantity of flow of air flow between the main outlet E5 and the sub outlet E6 is designed as follows: the quantity of flow of air flow of the main outlet E5: the quantity of flow of air flow of the sub outlet E6=6:4, so when the fan is maintained in a dual outlet state, the quantity of flow of air flow of the main outlet E5 drops to 0.72 units, while the quantity of flow of air flow of the sub outlet E6 is 0.48 units. Therefore, based on the air flow characteristics of the fan, supplemented by the control unit 150 that can control the opening and closing status of the sub outlet E6 by driving the gate 160, the air flow may be effectively distributed and optimized. In other words, the heat dissipation and operational flexibility of the heat dissipation system 100 may be improved without increasing the number of fans and maintaining the internal space of the portable electronic device.

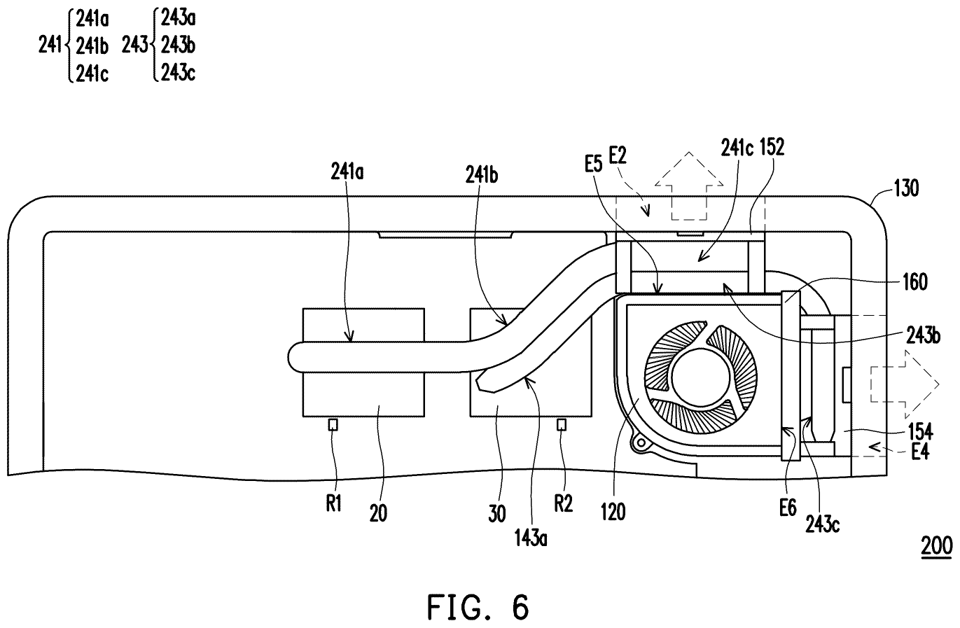

FIG. 6 is a schematic diagram of a heat dissipation system according to another embodiment of the disclosure. Referring to FIG. 6, according to this embodiment, a heat dissipation system 200 includes the second fan 120 and heat pipes 241 and 243, which are equivalent to the configuration of the second fan 120 on the right side retained in the previous embodiment. The heat pipes 241 and 243 are equivalent to the partial first heat pipe 141 and the second heat pipe 142. The heat pipe 241 has a heat absorption section 241a thermally contacting the heat source 20, a heat absorption section 241b thermally contacting the heat source 30, and a heat dissipation section 241c thermally contacting the heat dissipation fin set 152, so that the heat may be dissipated in the heat dissipation section 241c after the heat is absorbed from the heat sources 20 and 30. The heat pipe 243 has a heat absorption section 243a thermally contacting the heat source 30, a heat dissipation section 243b thermally contacting the heat dissipation fin set 152, and a heat dissipation section 243b thermally contacting the heat dissipation fin set 154, so that the heat may be dissipated in the heat dissipation sections 243b and 243c respectively after the heat is absorbed from the heat source 30. In other words, the disclosure has been able to distribute the quantity of air flow and improve the efficiency of the heat dissipation system 200 for multiple heat sources 20 and 30 with a single fan.

To sum up, according to the embodiments of the disclosure, the portable electronic device has multiple heat sources, the fan of the heat dissipation system has the main outlet and the sub outlet, and the heat sources thermally contact the heat dissipation fin at the main outlet and the sub outlet by different heat pipes, and the sub outlet is controlled by the gate to open or close to form a two-way heat dissipation path or a one-way heat dissipation path. In this way, the control unit may correspondingly open and close the sub outlet according to the respective load state of the heat sources, and use the two-way heat dissipation path or the one-way heat dissipation path as a heat dissipation means to meet different heat dissipation needs, so that the heat dissipation system may improve the heat dissipation efficiency and optimize the operation efficiency.

It will be apparent to those skilled in the art that various modifications and variations can be made to the disclosed without departing from the scope or spirit of the disclosure. In view of the foregoing, it is intended that the disclosure covers modifications and variations provided that they fall within the scope of the following claims and their equivalents.

What is claimed is:

1. A heat dissipation system suitable for a portable electronic device, wherein the portable electronic device has a first heat source, a second heat source, and a casing receiving the first and the second heat sources, and the heat dissipation system disposed in the casing comprises:
a first centrifugal fan, having a first main outlet and a first sub outlet;
a first gate disposed at the first sub outlet, wherein the first heat source provides heat transferring to the first main outlet, and the second heat source provides heat transferring to the first main outlet and the first sub outlet; and
a control unit electrically connected to the first gate, wherein the control unit drives the first gate to open or close the first sub outlet according to a load of the first and the second heat sources,
wherein the first main outlet is located at a rear side of the casing, the first sub outlet is located at a first side of the casing, and the portable electronic device is operable by a user from a front side of the casing, the front side and the rear side being opposite to each other.

2. The heat dissipation system according to claim 1 further comprising a first temperature sensor disposed beside the first heat source and a second temperature sensor disposed beside the second heat source, wherein the first and the second temperature sensors do not affect each other to sense temperature of the first and the second heat sources respectively, the first and the second temperature sensors are respectively electrically connected to the control unit, and the control unit drives the first gate to open or close the sub outlet based on the temperature values sensed by the first and the second temperature sensors.

3. The heat dissipation system according to claim 1, wherein, provided that fan blades rotate at the same speed, the quantity of air flow when the first main outlet and the first sub outlet are both open is 120% of the quantity of air flow when the first main outlet is open and the first sub outlet is closed.

4. The heat dissipation system according to claim 1, wherein the ratio of the quantity of air flow through the first main outlet to the quantity of air flow of the first sub outlet is 6:4.

5. The heat dissipation system according to claim 1, wherein the first heat source is a central processing unit and the second heat source is a display chip.

6. The heat dissipation system according to claim 1, further comprises:
a first heat dissipation fin set disposed at the main outlet of the first centrifugal fan;
a second heat dissipation fin set disposed at the sub outlet of the first centrifugal fan;
a first heat pipe thermally contacting the first heat source, the second heat source, and the first heat dissipation fin set, wherein the first heat pipe transfer heat from the first and the second heat sources to the first heat dissipation fin set; and
a second heat pipe thermally contacting the second heat source, the first heat dissipation fin set, and the second heat dissipation fin set, wherein the second heat pipe transfer heat from the second heat source to the second heat dissipation fin set.

7. The heat dissipation system according to claim 6 further comprising a third heat pipe, a second centrifugal fan, a second gate, a third heat dissipation fin set, and a fourth heat dissipation fin set, wherein the third heat dissipation fin set is located at a second main outlet of the second centrifugal fan, the fourth heat dissipation fin set is located at a second sub outlet of the second centrifugal fan, the second gate is located at the second sub outlet of the second centrifugal fan, the third heat pipe thermally contacts the first heat source, the third heat dissipation fin set, and the fourth heat dissipation fin set, the first heat pipe further thermally contacts the third heat dissipation fin set located at the second main outlet of the second centrifugal fan, the second gate is electrically connected to the control unit, and the control unit drives the second gate to open or close the second sub outlet of the second centrifugal fan according to heat output of the first and the second heat sources.

8. The heat dissipation system according to claim 7, wherein the first and the second heat sources are located between the first centrifugal fan and the second centrifugal fan.

9. The heat dissipation system according to claim 7, wherein the casing further has a second side and a plurality of exhaust vents, the second side is opposite to the first side, and the plurality of exhaust vents are respectively located at the first side, the rear side, and the second side to correspond to the first main out at the rear side, the second main outlet at the rear side, the first sub outlet at the first side, and the second sub outlet at the second side.

10. The heat dissipation system according to claim 1, wherein the casing has a plurality of exhaust vents to correspond to the first main outlet and the first sub outlet respectively.
